(19) United States
(12) Patent Application Publication
(10) Pub. No.: US 2025/0271759 A1
(43) Pub. Date: Aug. 28, 2025

(54) POLYMER, POSITIVE PHOTORESIST COMPOSITION, AND METHOD FOR FORMING PATTERNED PHOTORESIST LAYER

(71) Applicant: INDUSTRIAL TECHNOLOGY RESEARCH INSTITUTE, Hsinchu (TW)

(72) Inventors: Yu-Ying HSU, Hsinchu City (TW); Yao-Jheng HUANG, Taipei City (TW); Ming-Tzung WU, Hsinchu City (TW); Chin-Hua CHANG, Sanwan Township (TW); Te-Yi CHANG, Taoyuan City (TW)

(73) Assignee: INDUSTRIAL TECHNOLOGY RESEARCH INSTITUTE, Hsinchu (TW)

(21) Appl. No.: 18/895,882

(22) Filed: Sep. 25, 2024

(30) Foreign Application Priority Data
Feb. 22, 2024 (TW) 113106345

(51) Int. Cl. G03F 7/039; G03F 7/004; G03F 7/32

(52) U.S. Cl. CPC G03F 7/039; G03F 7/0045; G03F 7/322

(57) ABSTRACT

A polymer, positive photoresist composition, and method for forming a patterned photoresist layer are provided. The polymer includes a first repeating unit and a second repeating unit. The first repeating unit has a structure of Formula (I) and the second repeating unit has a structure of Formula (II)

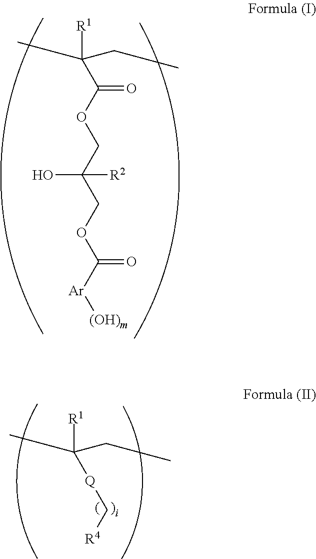

wherein R¹, R², R³, R⁴, Q, Ar, n, m, an i are as defined in the specification.

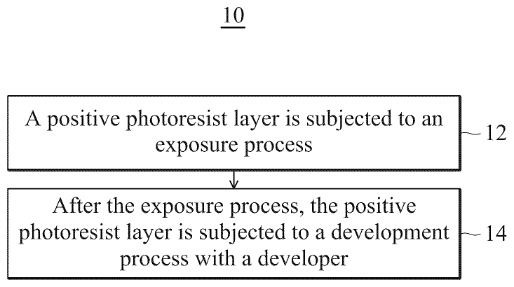

### CROSS REFERENCE TO RELATED APPLICATIONS

This application claims priority of Taiwan Patent Application No. 113106345, filed on Feb. 22, 2024, the entirety of which is incorporated by reference herein.

### TECHNICAL FIELD

The disclosure relates to a polymer, positive photoresist composition, and a method for forming a patterned photoresist layer.

### BACKGROUND

With the continuous advancements in integrated circuit manufacturing and packaging technologies, printed circuit boards (PCBs) have been developed to achieve high-density wiring, miniaturization, high electrical properties, high dimensional stability, high resolution, and lower costs. There is also an increasing demand for multilayer technologies with smaller pore sizes and higher alignment precision.

In the manufacturing process of printed circuit boards, to achieve high-density wiring and high resolution, it is necessary to further reduce the line width (such as less than or equal to 10 μm) of the photosensitive patterned photoresist layer. Additionally, it is also important to reduce the manufacturing cost of the photoresist layer (for instance, employing a weak alkaline developer such as 1% sodium carbonate aqueous solution). Therefore, photosensitive photoresist materials that exhibit high resolution, have a low manufacturing cost, and can be exposed with near-ultraviolet light, developed with a weak alkaline developer, are highly desired.

Although liquid photoresist compositions can form photosensitive photoresist material patterns with better resolution, the process of forming these patterns becomes more complex and difficult as the substrate size increases, leading to higher manufacturing costs. Furthermore, liquid photoresist compositions are generally used in ultra-fine processing (such as semiconductor manufacturing) and are developed with tetramethylammonium aqueous solutions. Since liquid photoresist compositions cannot be dissolved in weak alkaline developer (such as 1% sodium carbonate aqueous solution), they cannot be applied in the printed circuit board manufacturing process.

Negative photoresists are suitable for dry film technology to manufacture large-scale, low-resolution devices. However, the resolution of negative dry film photoresists is insufficient, limiting the use of dry film technology in high-resolution applications.

Accordingly, a novel photoresist composition with low cost, high performance and being suitable for high-resolution printed circuit board manufacturing is called for to solve the aforementioned problems.

### SUMMARY

The disclosure provides a polymer. According to embodiments of the disclosure, the polymer includes a first repeating unit and a second repeating unit. The first repeating unit has a structure of Formula (I) and the second repeating unit has a structure of Formula (II)

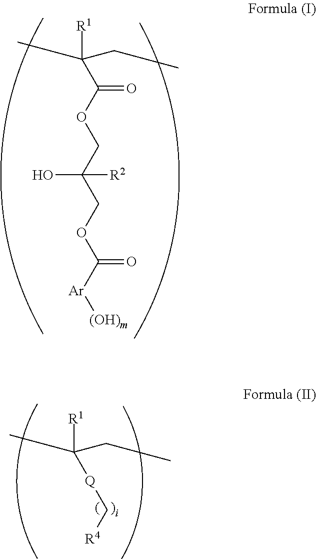

wherein, R¹, R² and R³ are independently hydrogen or C1-C4 alkyl group; Ar is substituted or non-substituted C6-C12 aryl group, wherein m number of hydrogen is substituted by hydroxyl group; R⁴ is hydrogen, C1-C8 alkyl group, or substituted or non-substituted C6-C12 aryl group; Q is a single bond or

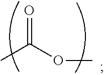

n is 0, 1, 2, 3 or 4; m is 1, 2 or 3; and, i is 0, 1, 2, 3 or 4.

The disclosure provides a positive photoresist composition for forming a patterned photoresist layer. According to embodiments of the disclosure, the positive photoresist composition includes the polymer of the disclosure and a photoacid generator.

The disclosure provides a method for forming a patterned photoresist layer. According to embodiments of the disclosure, the method includes following steps. A positive photoresist layer is subjected to an exposure process, wherein the positive photoresist layer is prepared by subjecting the positive photoresist composition of the disclosure to a drying process. The positive photoresist layer is subjected to a development process with a developer after the exposure process, obtaining the patterned photoresist layer of the disclosure.

### BRIEF DESCRIPTION OF THE DRAWINGS

The present disclosure can be more fully understood by reading the subsequent detailed description and examples with references made to the accompanying drawings, wherein:

Figure is a flow chart illustrating the method for forming patterned photoresist layer 10 according to an embodiment of the disclosure.

### DETAILED DESCRIPTION

The polymer, positive photoresist composition and method for forming patterned photoresist layer of the disclosure are described in detail in the following description. In the following detailed description, for purposes of explanation, numerous specific details and embodiments are set forth in order to provide a thorough understanding of the present disclosure. The specific elements and configurations described in the following detailed description are set forth in order to clearly describe the present disclosure. It will be apparent, however, that the exemplary embodiments set forth herein are used merely for the purpose of illustration, and the inventive concept may be embodied in various forms without being limited to those exemplary embodiments. As used herein, the term “about” in quantitative terms refers to plus or minus an amount that is general and reasonable to persons skilled in the art.

Furthermore, the use of ordinal terms such as “first”, “second”, “third”, etc., in the disclosure to modify an element does not by itself connote any priority, precedence, order of one claim element over another or the temporal order in which it is formed, but are used merely as labels to distinguish one claim element having a certain name from another element having the same name (but for use of the ordinal term) to distinguish the claim elements.

The disclosure provides a polymer, a positive photoresist composition employing the same, and a method for forming a patterned photoresist layer. Due to the alkali-soluble properties of the polymer of the disclosure (such as being soluble in sodium carbonate (Na₂CO₃) aqueous solution), the polymer may be applied in positive photoresist compositions for preparing a high-resolution positive dry film photosensitive layer (such as forming patterns with a line width of less than or equal to 10 μm). Since the positive photoresist composition of the disclosure and the dry film photosensitive layer prepared therefrom have good photosensitivity and light transmittance, enabling the achievement of high clarity and high precision wiring patterns. Furthermore, due to the pattern having good adhesion to the substrate during pattern formation and being peelable from the substrate after pattern formation, the wiring pattern formation process is simplified. In addition, in comparison with conventional photosensitive phenol resin compositions, the positive photoresist composition including the polymer of the disclosure can be developed in sodium carbonate (Na₂CO₃) aqueous solution, thereby making it suitable for use in printed circuit board processes (such as high-resolution printed circuit boards).

According to embodiments of the disclosure, the polymer can include a first repeating unit and a second repeating unit, wherein the first repeating unit has a structure of Formula (I), and the second repeating unit has a structure of Formula (II)

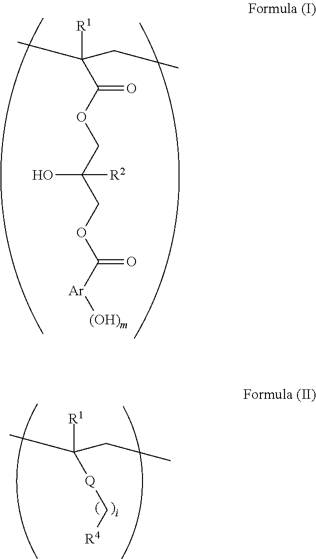

wherein R¹, R² and R³ are independently hydrogen or C1-C4 alkyl group; Ar may be substituted or non-substituted C6-C12 aryl group, wherein m number of hydrogen in the aryl group may be substituted by hydroxyl group; R⁴ may be hydrogen, C1-C8 alkyl group, or substituted or non-substituted C6-C12 aryl group; Q may be a single bond or

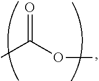

n may be 0, 1, 2, 3 or 4; m may be 1, 2 or 3; and, i may be 0, 1, 2, 3 or 4.

According to embodiments of the disclosure, when Q is

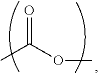

i may be 1, 2, 3 or 4.

According to embodiments of the disclosure, substituted C6-C12 aryl group means that at least one of the hydrogen bonded with the carbon of the aryl group can be optionally replaced with fluorine, C1-C8 alkyl group, C1-C8 fluoroalkyl group or C1-C8 alkoxy group.

According to embodiments of the disclosure, the polymer can include at least one of the first repeating units and at least one of the second repeating units. Namely, the polymer can include at least one repeating unit having a structure represented by Formula (I), and at least one repeating unit having a structure represented by Formula (II).

According to embodiments of the disclosure, the first repeating unit may be

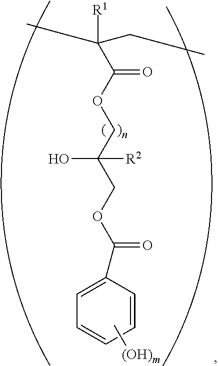

wherein R¹, R², n and m are the same as defined above.

According to embodiments of the disclosure, the first repeating unit may be

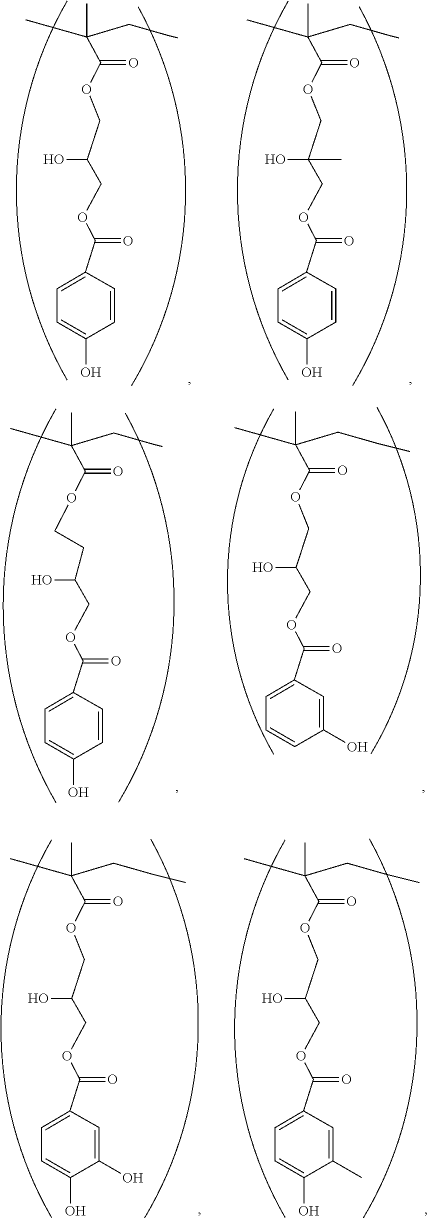

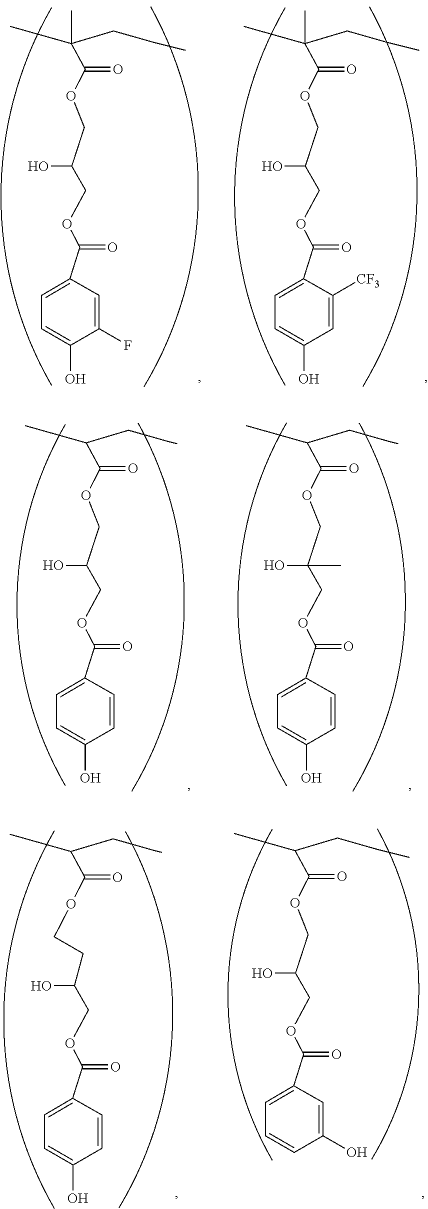

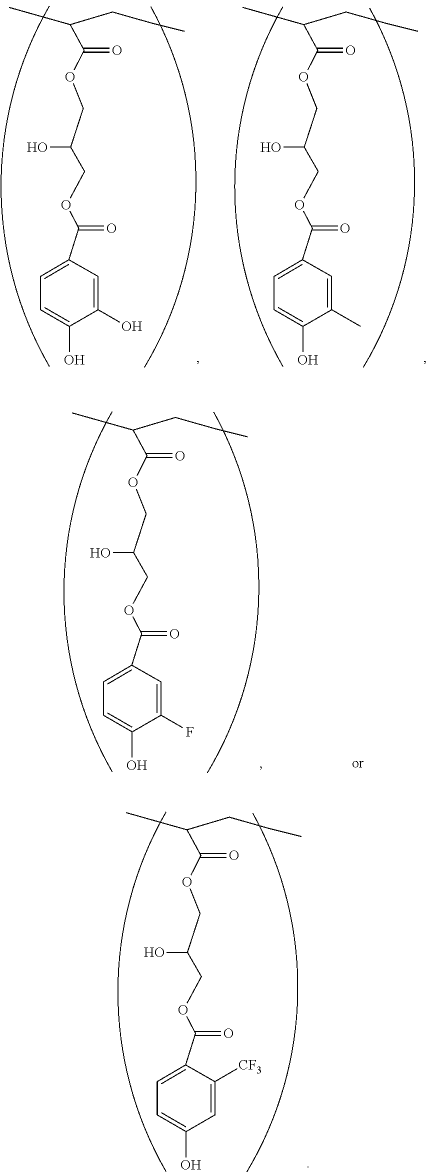

According to embodiments of the disclosure, the second repeating unit may be

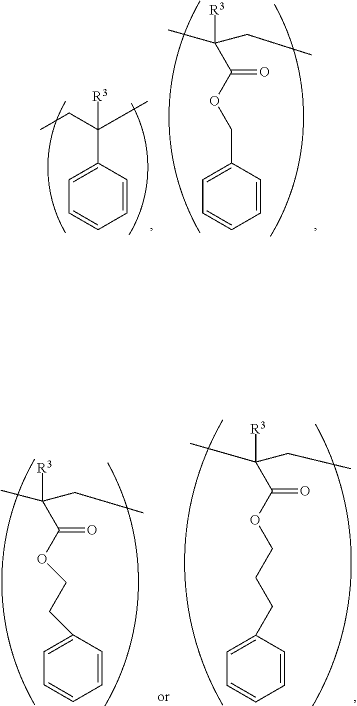

wherein R³ is the same as defined above.

According to embodiments of the disclosure, the second repeating unit may be

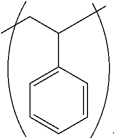

According to embodiments of the disclosure, the alkyl group of the disclosure may be a linear or branched alkyl group.

For example, C1-C8 alkyl group may be methyl, ethyl, propyl, butyl, pentyl, hexyl, heptyl, octyl or an isomer thereof.

According to embodiments of the disclosure, the fluoroalkyl group of the disclosure may be a linear or branched alkyl group in which a part of or all hydrogen atoms bonded on the carbon atoms are replaced with fluorine atoms.

For example, C1-C8 fluoroalkyl group may be fluoromethyl, fluoroethyl, fluoropropyl, fluorobutyl, fluoropentyl, fluorohexyl, fluoroheptyl, fluorooctyl or an isomer thereof. Herein, fluoromethyl group may be monofluoromethyl group, difluoromethyl group or trifluoromethyl group, and fluoroethyl may be monofluoroethyl group, difluoroethyl group, trifluoroethyl group, tetrafluoroethyl group, or perfluoroethyl group.

According to embodiments of the disclosure, the alkoxy group of the disclosure may be a linear or branched alkoxy group.

For example, C1-C8 alkoxy group may be methoxy, ethoxy, propoxy, butoxy, pentoxy, hexoxy or an isomer thereof.

According to embodiments of the disclosure, the C6-C12 aryl group of the disclosure may be phenyl group, biphenyl group or naphthyl group.

According to embodiments of the disclosure, the repeating unit of the polymer may consist of the first repeating unit and the second repeating unit. According to embodiments of the disclosure, the polymer does not include any repeating units other than the first repeating unit and the second repeating unit.

According to embodiments of the disclosure, the first repeating unit and the second repeating unit may be arranged in a random or block fashion.

According to embodiments of the disclosure, in the polymer of the disclosure, the number ratio of the first repeating unit to the second repeating unit may be 9:1 to 1:9, such as 8:2, 7:3, 6:4, 5:5, 4:6, 3:7 or 2:8. As a result, the positive photoresist composition employing the polymer of the disclosure can be developed with a weakly alkaline developer (such as sodium carbonate aqueous solution). Further, the amount of the photoacid generator can be reduced due to the use of the polymer of the disclosure.

According to embodiments of the disclosure, apart from the first repeating unit and the second repeating unit, when the polymer further includes other repeating units, the ratio of the total number of the first repeating unit and the second repeating unit to the total number of all repeating units is 90:100 to 99.9:100.

According to embodiments of the disclosure, the weight average molecular weight of the polymer of the disclosure may be 5,000 g/mol to 50,000 g/mol, such as 6,000 g/mol, 7,000 g/mol, 8,000 g/mol, 9,000 g/mol, 10,000 g/mol, 15,000 g/mol, 20,000 g/mol, 25,000 g/mol, 30,000 g/mol, 35,000 g/mol, 40,000 g/mol or 45,000 g/mol. The weight average molecular weight (Mw) of the polymer of the disclosure can be determined by gel permeation chromatography (GPC) based on a polystyrene calibration curve.

The polymer of the disclosure may be prepared from a first monomer and a second monomer via polymerization. In the polymer of the disclosure, the first repeating unit is derived from the first monomer, and the second repeating unit is derived from the second monomer.

According to embodiments of the disclosure, the first monomer may be

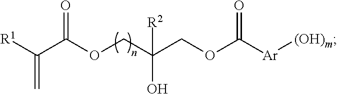

the second monomer may be

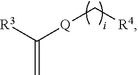

wherein R¹, R², R³, R⁴, Q, Ar, n, m, and i are the same as defined above.

According to embodiments of the disclosure, the first monomer may be

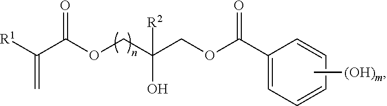

wherein R¹, R², n, and m are the same as defined above; and, the second monomer may be

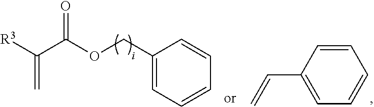

wherein R³ may be hydrogen or methyl, and i may be 1, 2, 3 or 4.

According to embodiments of the disclosure, in the preparation of the polymer of the disclosure, the molar ratio of the first monomer to the second monomer may be 9:1 to 1:9, such as 8:2, 7:3, 6:4, 5:5, 4:6, 3:7 or 2:8.

The preparation method of the polymer of the disclosure is not limited. For example, the first monomer may be mixed with the second monomer to undergo a copolymerization in the presence of a chain transfer agent and/or catalyst (with a reaction temperature of 50° C. to 150° C. and a reaction time period of 1 hour to 12 hours). In addition, the first monomer may be subjected to a homopolymerization reaction at first to obtain a first oligomer, and the second monomer may be subjected to a homopolymerization reaction at first to obtain a second oligomer. Next, the first oligomer and the second oligomer are mixed and copolymerized in the presence of a chain transfer agent and/or catalyst (with a reaction temperature of 50° C. to 150° C. and a reaction time period of 1 hour to 12 hours). According to embodiments of the disclosure, the chain transfer agent and the catalyst are not limited and may be the chain transfer agents and catalysts commonly used in copolymerization.

According to embodiments of the disclosure, the disclosure also provides a positive photoresist composition. The positive photoresist composition can include the polymer of the disclosure, and a photoacid generator.

According to embodiments of the disclosure, the positive photoresist composition of the disclosure has high photosensitivity, a low dielectric coefficient, and high light transmittance. As a result, the dry film prepared from the positive photoresist composition of the disclosure can achieve high clarity and high precision wiring patterns.

According to embodiments of the disclosure, the weight ratio of the polymer of the disclosure to the photoacid generator may be 2:1 to 12:1, such as 3:1, 4:1, 5:1, 6:1, 7:1, 8:1, 9:1, 10:1 or 11:1.

According to embodiments of the disclosure, the photoacid generator may be an onium salt, triarylsulfonium salt, alkylarylsulfonium salt, diaryliodonium salt, diarylchloronium salt, diarylbromonium salt, sulfonate salt, diazonium salt, diazonaphthoquinone sulfonate, or a combination thereof.

According to embodiments of the disclosure, in the positive photoresist composition of the disclosure, the polymer of the disclosure and the photoacid generator can be evenly dissolved in an organic solvent.

According to embodiments of the disclosure, the organic solvent may be benzene, toluene, xylene, ethylbenzene, diethylbenzene, trimethylbenzene, triethylbenzene, cyclohexane, cyclohexene, decahydronaphthalene, dipentene, pentane, hexane, heptane, octane, nonane, decane, ethyl cyclohexane, methyl cyclohexane, p-menthane, dipropyl ether, dibutyl ether, anisole, ethyl acetate, butyl acetate, pentyl acetate, methyl isobutyl ketone, cyclohexylbenzene, cyclohexanone, cyclopentanone (CPN), triglyme, 1,3-dimethyl-2-imidazolidinone (DMI), N-methyl-2-pyrrolidone (NMP), methyl ethyl ketone (MEK), N,N-dimethylacetamide (DMAc), 7-butyrolactone (GBL), N,N-dimethylformamide (DMF), propylene glycol methyl ether acetate (PGMEA), dimethyl sulfoxide (DMSO), or a combination thereof.

According to embodiments of the disclosure, in order to achieve desired properties of the positive photoresist composition or the dry film therefrom, additives such as leveling agents, colorants, adhesion promoters, thixotropic agents, sensitizers, fillers, or a combination thereof may be optionally added into the composition. According to embodiments of the disclosure, the amount of additives may be 0.1 wt % to 30 wt %, based on the total weight of the polymer and the photoacid generator.

According to embodiments of the disclosure, when the positive photoresist composition of the disclosure includes an organic solvent, the positive photoresist composition may have a solid content of about 10% to 50% (such as 15%, 20%, 25%, 30%, 35%, 40% or 45%). The solid content refers to the weight percentage of all components in the positive photoresist composition except for the organic solvent, based on the total weight of the composition.

The disclosure also provides a method for forming a patterned photoresist layer. As shown in Figure, the method for forming patterned photoresist layer 10 of the disclosure includes following steps. A positive photoresist layer is subjected to an exposure process (step 12), wherein the positive photoresist layer is prepared from the positive photoresist composition of the disclosure. Next, the positive photoresist layer is subjected to a development process with a developer (step 14) after the exposure process, obtaining a patterned photoresist layer.

According to embodiments of the disclosure, the light source for the exposure process may be ultraviolet (UV) light (with a wavelength ranging from 150 nm to 450 nm). The exposure dose of the exposure process may be 10 mJ/cm² to 500 mJ/cm² (such as 20 mJ/cm², 50 mJ/cm², 70 mJ/cm², 100 mJ/cm², 120 mJ/cm², 150 mJ/cm², 200 mJ/cm², 250 mJ/cm², 300 mJ/cm², 350 mJ/cm², 400 mJ/cm² or 450 mJ/cm²).

According to embodiments of the disclosure, the developer may be an alkali metal salt aqueous solution, such as sodium carbonate aqueous solution or potassium carbonate aqueous solution. According to embodiments of the disclosure, in the alkali metal salt aqueous solution, the amount of alkali metal salt may be 0.1 wt to 5 wt %, based on the total weight of the alkali metal salt aqueous solution.

According to embodiments of the disclosure, the positive photoresist layer may be a dry film prepared by subjecting the positive photoresist composition of the disclosure to a coating process and a drying process.

According to embodiments of the disclosure, the preparation and use of the positive dry film photoresist according to the disclosure may include the following steps. First, the positive photoresist composition is coated onto a carrier film. After drying, a protective film is laminated onto the dried photoresist composition to form the positive dry film photoresist. During transfer printing, the protective film is removed, and the dried photoresist composition is transferred onto a substrate by a transfer printing process. Then, the carrier film is removed, and the exposure process and development process can be performed.

The coating method of the positive photoresist composition mentioned above is not limited and may include screen printing, spin coating, bar coating, blade coating, roller coating, dip coating, spray coating, or brush coating.

According to embodiments of the disclosure, the carrier film and protective film may be polyethylene terephthalate (PET) film, polyethylene (PE) film, or oriented polypropylene (OPP) film. According to embodiments of the disclosure, the substrate may be a wafer or copper-clad laminate.

Below, exemplary embodiments will be described in detail with reference to the accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

### Preparation of Polymer

### Preparation Examples 1-5

Glycidyl methacrylate (GMA) (375 g), 4-hydroxybenzoic acid (367.5 g), catalyst (triphenylphosphine) (1.88 g), and inhibitor (hydroquinone) (1.05 g) were added into a solvent (propylene glycol methyl ether acetate (PGMEA)) (320 g), obtaining a mixture. The mixture was stirred at 100° C. for 4 hours. After purification, Monomer (I) (with a structure of

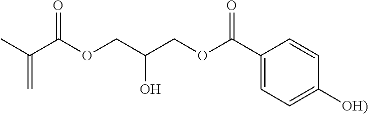

was obtained.

Monomer (I), benzyl methacrylate (with a structure of

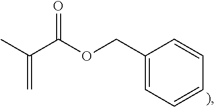

catalyst (2,2′-azobis(2-methylpropionitrile (AIBN)), chain transfer agent (1-dodecanethiol), and solvent (propylene glycol methyl ether acetate (PGMEA)) were mixed according to the amounts as disclosed in Table 1. The resulting mixture was heated to 90° C. and stirred for 4 hours to obtain Polymers (1)-(5) individually. The weight average molecular weight (Mw) of Polymers (1)-(5) were measured by gel permeation chromatography (GPC), and the results are shown in Table 1.

### Preparation Examples 6-9

Monomer (I), styrene, catalyst (2,2′-azobis(2-methylpropionitrile (AIBN)), chain transfer agent (1-dodecanethiol), and solvent (propylene glycol methyl ether acetate (PGMEA)) were mixed according to the amounts as disclosed in Table 1. The resulting mixture was heated to 90° C. and stirred for 4 hours to obtain Polymers (6)-(9) individually. The weight average molecular weight (Mw) of Polymers (6)-(9) were measured by gel permeation chromatography (GPC), and the results are shown in Table 1.

TABLE 1

| | molar ratio | total weight of | | chain | | weight |
|---|---|---|---|---|---|---|
| | of Monomer | Monomer (I) | | transfer | | average |
| | (I) to benzyl | and benzyl | catalyst | agent | solvent | molecular |
| | methacrylate | methacrylate (g) | (g) | (g) | (g) | weight |
| Preparation | 9:1 | 308 | 5.779 | 5.779 | 1150 | 7,406 |
| Example 1 | | | | | | |
| Polymer (1) | | | | | | |
| Preparation | 7:3 | 293 | 6.935 | 6.935 | 340 | 19,169 |
| Example 2 | | | | | | |
| Polymer (2) | | | | | | |
| Preparation | 5:5 | 230 | 6.000 | 6.000 | 302 | 13,304 |
| Example 3 | | | | | | |
| Polymer (3) | | | | | | |
| Preparation | 4:6 | 220 | 5.997 | 5.997 | 106 | 11,735 |
| Example 4 | | | | | | |
| Polymer (4) | | | | | | |
| Preparation | 3:7 | 210 | 6.004 | 6.004 | 112 | 9,560 |
| Example 5 | | | | | | |
| Polymer (5) | | | | | | |
| Preparation | 7:3 | 227.6 | 6.000 | 6.000 | 258 | 22,800 |
| Example 6 | | | | | | |
| Polymer (6) | | | | | | |
| Preparation | 6:4 | 192.6 | 6.000 | 6.000 | 232 | 25,758 |
| Example 7 | | | | | | |
| Polymer (7) | | | | | | |
| Preparation | 5:5 | 175.1 | 6.000 | 6.000 | 68 | 25,328 |
| Example 8 | | | | | | |
| Polymer (8) | | | | | | |
| Preparation | 3:7 | 157.6 | 6.000 | 6.000 | 71 | 17,846 |
| Example 9 | | | | | | |
| Polymer (9) | | | | | | |

### Preparation of Positive Photoresist Composition

### Examples 1-3

Polymer (1), 2,3,4-trihydroxybenzophenone naphthoquinone-1,2-diazido-5-sulfonate (DNQ) (photoacid generator), butyl acetate (BA) (solvent), and propylene glycol methyl ether acetate (PGMEA) (solvent) were mixed according to the amounts as disclosed in Table 2. After thoroughly mixing, Positive photoresist composition (1)-(3) were obtained.

### Examples 4-6

Polymer (2), 2,3,4-trihydroxybenzophenone naphthoquinone-1,2-diazido-5-sulfonate (DNQ) (photoacid generator), butyl acetate (BA) (solvent) and propylene glycol methyl ether acetate (PGMEA) (solvent) were mixed according to the amounts as disclosed in Table 2. After thoroughly mixing, Positive photoresist composition (4)-(6) were obtained.

### Examples 7-9

Polymer (3), 2,3,4-trihydroxybenzophenone naphthoquinone-1,2-diazido-5-sulfonate (DNQ) (photoacid generator), butyl acetate (BA) (solvent) and propylene glycol methyl ether acetate (PGMEA) (solvent) were mixed according to the amounts as disclosed in Table 2. After thoroughly mixing, Positive photoresist composition (7)-(9) were obtained.

### Examples 10-12

Polymer (4), 2,3,4-trihydroxybenzophenone naphthoquinone-1,2-diazido-5-sulfonate (DNQ) (photoacid generator), butyl acetate (BA) (solvent) and propylene glycol methyl ether acetate (PGMEA) (solvent) were mixed according to the amounts as disclosed in Table 2. After thoroughly mixing, Positive photoresist composition (10)-(12) were obtained.

### Examples 13-15

Polymer (5), 2,3,4-trihydroxybenzophenone naphthoquinone-1,2-diazido-5-sulfonate (DNQ) (photoacid generator), butyl acetate (BA) (solvent) and propylene glycol methyl ether acetate (PGMEA) (solvent) were mixed according to the amounts as disclosed in Table 2. After thoroughly mixing, Positive photoresist composition (13)-(15) were obtained.

TABLE 2

| | Polymer | Polymer | Polymer | Polymer | Polymer | DNQ | BA | PGME |
|---|---|---|---|---|---|---|---|---|
| | (1) (g) | (2) (g) | (3) (g) | (4) (g) | (5) (g) | (g) | (g) | A (g) |
| Positive photoresist | 18.25 | — | — | — | — | 4.75 | 7.7 | 69.3 |
| composition (1) | | | | | | | | |
| Positive photoresist | 18.33 | — | — | — | — | 3.67 | 7.8 | 70.2 |
| composition (2) | | | | | | | | |
| Positive photoresist | 18.42 | — | — | — | — | 2.58 | 7.9 | 71.1 |
| composition (3) | | | | | | | | |
| Positive photoresist | — | 25.00 | — | — | — | 5 | 7.0 | 63.0 |
| composition (4) | | | | | | | | |
| Positive photoresist | — | 25.42 | — | — | — | 4.58 | 7.0 | 63.0 |
| composition (5) | | | | | | | | |
| Positive photoresist | — | 25.86 | — | — | — | 4.14 | 7.0 | 63.0 |
| composition (6) | | | | | | | | |
| Positive photoresist | — | — | 25.42 | — | — | 4.58 | 7.0 | 63.0 |
| composition (7) | | | | | | | | |
| Positive photoresist | — | — | 25.86 | — | — | 4.14 | 7.0 | 63.0 |
| composition (8) | | | | | | | | |
| Positive photoresist | — | — | 26.32 | — | — | 3.68 | 7.0 | 63.0 |
| composition (9) | | | | | | | | |
| Positive photoresist | — | — | — | 26.32 | — | 3.68 | 7.0 | 63.0 |
| composition (10) | | | | | | | | |
| Positive photoresist | — | — | — | 26.79 | — | 3.21 | 7.0 | 63.0 |
| composition (11) | | | | | | | | |
| Positive photoresist | — | — | — | 27.27 | — | 2.73 | 7.0 | 63.0 |
| composition (12) | | | | | | | | |
| Positive photoresist | — | — | — | — | 26.32 | 3.68 | 7.0 | 63.0 |
| composition (13) | | | | | | | | |
| Positive photoresist | — | — | — | — | 26.79 | 3.21 | 7.0 | 63.0 |
| composition (14) | | | | | | | | |
| Positive photoresist | — | — | — | — | 27.27 | 2.73 | 7.0 | 63.0 |
| composition (15) | | | | | | | | |

### Comparative Example 1

Phenol formaldehyde resin (1) (commercially available from Sumitomo Bakelite under the trade designation of PR56001) (with a weight average molecular weight (Mw) of about 5,000) (22.5 g), 2,3,4-trihydroxybenzophenone naphthoquinone-1,2-diazido-5-sulfonate (DNQ) (photoacid generator) (6.7 g), butyl acetate (BA) (7.08 g) (solvent), and propylene glycol methyl ether acetate (PGMEA) (63.72 g) (solvent) were mixed. After thoroughly mixing, Positive photoresist composition (16) was obtained.

### Comparative Example 2

Phenol formaldehyde resin (2) (commercially available from Sumitomo Bakelite under the trade designation of PR56032) (with a weight average molecular weight (Mw) of about 50,000) (22.5 g), 2,3,4-trihydroxybenzophenone naphthoquinone-1,2-diazido-5-sulfonate (DNQ) (photoacid generator) (6.7 g), butyl acetate (BA) (7.08 g) (solvent), and propylene glycol methyl ether acetate (PGMEA) (63.72 g) (solvent) were mixed. After thoroughly mixing, Positive photoresist composition (17) was obtained.

### Comparative Example 3

Poly(4-vinylphenol) (commercially available from Sigma-Aldrich) (with a weight average molecular weight (Mw) of about 11,000) (26.32 g), 2,3,4-trihydroxybenzophenone naphthoquinone-1,2-diazido-5-sulfonate (DNQ) (photoacid generator) (3.68 g), butyl acetate (BA) (7 g) (solvent), and propylene glycol methyl ether acetate (PGMEA) (63 g) (solvent) were mixed. After thoroughly mixing, Positive photoresist composition (18) was obtained.

### Examples 16-23

Polymer (6)-(9), 2,3,4-trihydroxybenzophenone naphthoquinone-1,2-diazido-5-sulfonate (DNQ) (photoacid generator), butyl acetate (BA) (solvent) and propylene glycol methyl ether acetate (PGMEA) (solvent) were mixed according to the amounts as disclosed in Table 3. After thoroughly mixing, Positive photoresist composition (19)-(26) were obtained.

TABLE 3

| | Polymer | Polymer | Polymer | Polymer | DNQ | BA | PGMEA |
|---|---|---|---|---|---|---|---|
| | (6) (g) | (7) (g) | (8) (g) | (9) (g) | (g) | (g) | (g) |
| Positive photoresist | 24.59 | — | — | — | 5.41 | 7 | 63 |
| composition (19) | | | | | | | |
| Positive photoresist | 23.81 | — | — | — | 6.19 | 7 | 63 |
| composition (20) | | | | | | | |
| Positive photoresist | — | 24.59 | — | — | 5.41 | 7 | 63 |
| composition (21) | | | | | | | |
| Positive photoresist | — | 23.81 | — | — | 6.19 | 7 | 63 |
| composition (22) | | | | | | | |
| Positive photoresist | — | — | 24.59 | — | 5.41 | 7 | 63 |
| composition (23) | | | | | | | |
| Positive photoresist | — | — | 23.81 | — | 6.19 | 7 | 63 |
| composition (24) | | | | | | | |
| Positive photoresist | — | — | — | 24.59 | 5.41 | 7 | 63 |
| composition (25) | | | | | | | |
| Positive photoresist | — | — | — | 23.81 | 6.19 | 7 | 63 |
| composition (26) | | | | | | | |

### Preparation of Dry Film Photoresist Layer

Positive photoresist compositions (1)-(26) were each coated onto a polyethylene terephthalate (PET) carrier film via blade coating. After drying at 80° C. to remove the solvent, Dry film photoresist layers (1)-(26) (with a thickness of about 6 μm) were obtained. Next, a polyethylene terephthalate (PET) protective film was laminated onto each dry film photoresist layer.

### Transfer Printing Test

The dry film photoresist layer on the carrier film was cut to obtain a test piece with a size of 7 cm×7 cm. After removing the protective film, the test piece was laminated onto a 10 cm×10 cm wafer. A roller was used to apply a pressure (about 2.5 kg/cm²) to the carrier film side, wherein the temperature of the roller was 95° C. and the speed of the roller was 0.2 m/min, thereby transferring the dry film photoresist layer onto the wafer. After removing the carrier film, if the dry film photoresist layer was completely transferred to the wafer (with no residue on the carrier film), it was marked as O. If the dry film photoresist layer was not completely transferred to the wafer (with residue on the carrier film), it was marked as X. The results are shown in Table 4.

### Evaluation of Resolution

The dry film photoresist layers (1)-(26) that underwent the transfer printing test were exposed to full-spectrum UV light (with a pattern line width of 8 μm and line space of 8 μm). Next, the dry film photoresist layers were developed with a sodium carbonate aqueous solution (for about 60-90 seconds). The exposure dose and the concentration of sodium carbonate aqueous solution are shown in Table 4. If the exposed and developed dry film photoresist layer produced a pattern with a line width and line pitch of 8 μm, it was marked as O; otherwise, it was marked as X.

TABLE 4

| | | | sodium | | |
|---|---|---|---|---|---|
| | | | carbonate | | |
| | | | aqueous | | |
| | transfer | exposure | solution | development | evaluation |
| | printing | dose | concentration | period | of |
| | test | (mJ/cm²) | (%) | (sec) | resolution |
| Dry film | ◯ | 100 | 0.5 | 60-90 | ◯ |
| photoresist | | | | | |
| layer (1) | | | | | |
| Dry film | ◯ | 100 | 0.5 | 60-90 | ◯ |
| photoresist | | | | | |
| layer (2) | | | | | |
| Dry film | ◯ | 100 | 0.5 | 60-90 | ◯ |
| photoresist | | | | | |
| layer (3) | | | | | |
| Dry film | ◯ | 50 | 1 | 60-90 | ◯ |
| photoresist | | | | | |
| layer (4) | | | | | |
| Dry film | ◯ | 50 | 1 | 60-90 | ◯ |
| photoresist | | | | | |
| layer (5) | | | | | |
| Dry film | ◯ | 75 | 1 | 60-90 | ◯ |
| photoresist | | | | | |
| layer (6) | | | | | |
| Dry film | ◯ | 100 | 2 | 60-90 | ◯ |
| photoresist | | | | | |
| layer (7) | | | | | |
| Dry film | ◯ | 100 | 2 | 60-90 | ◯ |
| photoresist | | | | | |
| layer (8) | | | | | |
| Dry film | ◯ | 100 | 2 | 60-90 | ◯ |
| photoresist | | | | | |
| layer (9) | | | | | |
| Dry film | ◯ | 100 | 2.5 | 60-90 | ◯ |
| photoresist | | | | | |
| layer (10) | | | | | |
| Dry film | ◯ | 100 | 2.5 | 60-90 | ◯ |
| photoresist | | | | | |
| layer (11) | | | | | |
| Dry film | ◯ | 100 | 2.5 | 60-90 | ◯ |
| photoresist | | | | | |
| layer (12) | | | | | |
| Dry film | ◯ | 100 | 3 | 60-90 | ◯ |
| photoresist | | | | | |
| layer (13) | | | | | |
| Dry film | ◯ | 100 | 3 | 60-90 | ◯ |
| photoresist | | | | | |
| layer (14) | | | | | |
| Dry film | ◯ | 100 | 3 | 60-90 | ◯ |
| photoresist | | | | | |
| layer (15) | | | | | |
| Dry film | X | 200 | 5 | 60-300 | X |
| photoresist | | | | | |
| layer (16) | | | | | |
| Dry film | X | 200 | 5 | 60-300 | X |
| photoresist | | | | | |
| layer (17) | | | | | |
| Dry film | X | 200 | 5 | 60-300 | X |
| photoresist | | | | | |
| layer (18) | | | | | |
| Dry film | ◯ | 50 | 1 | 60-90 | ◯ |
| photoresist | | | | | |
| layer (19) | | | | | |
| Dry film | ◯ | 50 | 1 | 60-90 | ◯ |
| photoresist | | | | | |
| layer (20) | | | | | |
| Dry film | ◯ | 70 | 1.5 | 60-90 | ◯ |
| photoresist | | | | | |
| layer (21) | | | | | |
| Dry film | ◯ | 70 | 1.5 | 60-90 | ◯ |
| photoresist | | | | | |
| layer (22) | | | | | |
| Dry film | ◯ | 100 | 2 | 60-90 | ◯ |
| photoresist | | | | | |
| layer (23) | | | | | |
| Dry film | ◯ | 100 | 2 | 60-90 | ◯ |
| photoresist | | | | | |
| layer (24) | | | | | |
| Dry film | ◯ | 200 | 3 | 60-90 | ◯ |
| photoresist | | | | | |
| layer (25) | | | | | |
| Dry film | ◯ | 200 | 3 | 60-90 | ◯ |
| photoresist | | | | | |
| layer (26) | | | | | |

In addition, Dry film photoresist layers (16), (17), and (18) of Comparative Examples 1, 2, and 3 were exposed at a higher exposure dose (increased to 200 mJ/cm) and developed with sodium carbonate aqueous solution of higher concentration (concentration increased to 5%) and for a longer duration (development time increased to 300 seconds). However, patterned photoresist layers could not be obtained.

As shown in Table 4, in comparison with conventional photosensitive phenol resin compositions, the positive photoresist composition including the polymer of the disclosure can be developed with a sodium carbonate aqueous solution. Therefore, the photoresist composition of the disclosure is suitable for printed circuit board processes.

Accordingly, due to the alkali-soluble property of the polymer of the disclosure, it can be used in positive photoresist compositions for preparing high-resolution photosensitive positive dry film. The positive photoresist composition and the dry film prepared therefrom exhibit good photosensitivity and light transmittance, enabling the formation of high-clarity and high-precision wiring patterns. Furthermore, due to the good adhesion of the pattern to the substrate during pattern formation and the good peelability of the pattern from the substrate after pattern formation, the wiring pattern formation process is simplified.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A polymer, which comprises a first repeating unit and a second repeating unit, wherein the first repeating unit has a structure of Formula (I) and the second repeating unit has a structure of Formula (II) 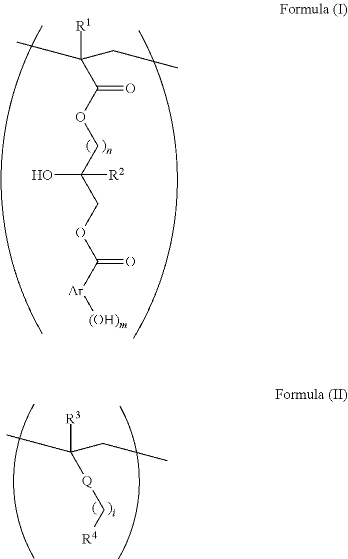
wherein, R¹, R² and R³ are independently hydrogen or C1-C4 alkyl group; Ar is a substituted or non-substituted aryl group, wherein m number of hydrogen is substituted by hydroxyl group; R⁴ is hydrogen, C1-C8 alkyl group, or substituted or non-substituted C6-C12 aryl group; Q is a single bond or 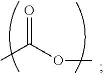
n is 0, 1, 2, 3 or 4; m is 1, 2 or 3; and, i is 0, 1, 2, 3 or 4.

2. The polymer as claimed in claim 1, wherein the first repeating unit and the second repeating unit are arranged in a random or block fashion.

3. The polymer as claimed in claim 1, wherein the first repeating unit and the second repeating unit has a number ratio of 9:1 to 1:9.

4. The polymer as claimed in claim 1, wherein the first repeating unit is

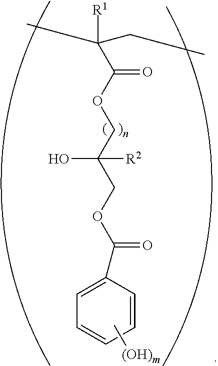

5. The polymer as claimed in claim 1, wherein the second repeating unit is

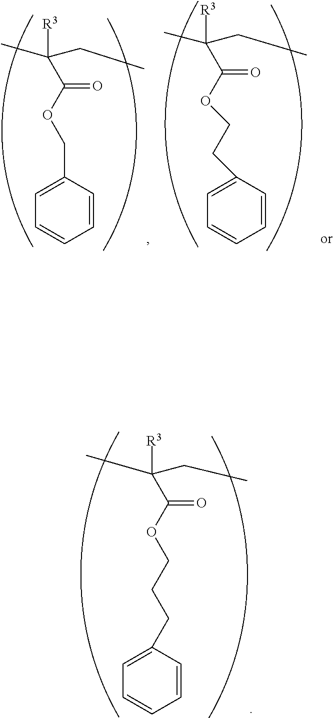

6. The polymer as claimed in claim 1, wherein the second repeating unit is

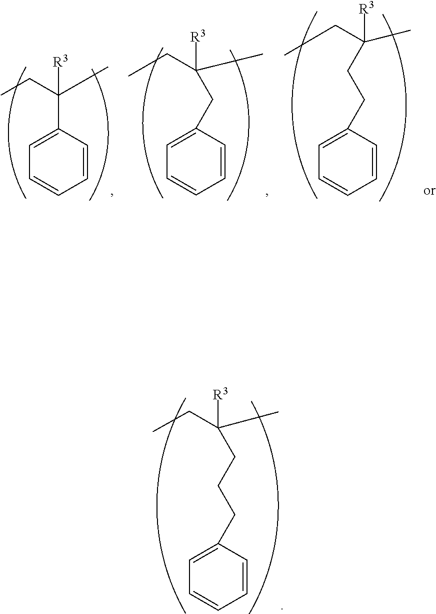

7. A positive photoresist composition, comprising:
the polymer as claimed in claim 1; and
a photoacid generator.

8. The positive photoresist composition as claimed in claim 7, wherein the photoacid generator is an onium salt, triarylsulfonium salt, alkylarylsulfonium salt, diaryliodonium salt, diarylchloronium salt, diarylbromonium salt, sulfonate salt, diazonium salt, diazonaphthoquinone sulfonate, or a combination thereof.

9. The positive photoresist composition as claimed in claim 7, wherein the polymer and the photoacid generator has a weight ratio of 2:1 to 12:1.

10. A method for forming a patterned photoresist layer, comprising:
subjecting a positive photoresist layer to an exposure process, wherein the positive photoresist layer is prepared from the positive photoresist composition as claimed in claim 7 via a drying process; and
subjecting the positive photoresist layer to a development process with a developer after the exposure process, obtaining a patterned photoresist layer.

11. The method for forming the patterned photoresist layer as claimed in claim 10, wherein the developer is an alkali metal salt aqueous solution, and an amount of an alkali metal salt of 0.1 wt to 5 wt % is in the alkali metal salt aqueous solution, based on a total weight of the alkali metal salt aqueous solution.
